(19) United States
(12) Patent Application Publication
(10) Pub. No.: US 2015/0333298 A1
(43) Pub. Date: Nov. 19, 2015

(54) HEATING VESSEL OF DETECTING AND PREVENTING LEAKAGE OF HIGH TEMPERATURE METAL MATERIAL AND MANUFACTURE METHOD THEREOF

(71) Applicant: Shenzhen China Star Optoelectronics Technology Co. Ltd., Shenzhen, Guangdong (CN)

(72) Inventors: Youyuan Kuang, Shenzhen (CN); Xindi Zhang, Shenzhen (CN)

(73) Assignee: Shenzhen China Star Optoelectronics Technology Co. Ltd., Shenzhen, Guangdong (CN)

(21) Appl. No.: 14/381,195

(22) PCT Filed: May 28, 2014
(86) PCT No.: PCT/CN2014/078677

§ 371 Date: Aug. 26, 2014

(30) Foreign Application Priority Data
May 14, 2014 (CN) 201410204509.8

(51) Int. Cl. H01L 51/56; B23K 31/02; B23K 31/12; G01N 27/20

(52) U.S. Cl. CPC H01L 51/56; G01N 27/20; B23K 31/02; B23K 31/12

(57) ABSTRACT

The present invention is related with a heating vessel of detecting and preventing leakage of high temperature metal material and a manufacture method thereof. The heating vessel comprises: an internal heating vessel employed for containing metal material, an external heating vessel employed to contain the internal heating vessel and to be heated by a heating apparatus and a detection apparatus; multiple bottom static wires are located between the internal heating vessel and the external heating vessel, where is close to the joint of a lateral side and a bottom of the internal heating vessel, and two ends of each of the bottom static wires are respectively connected to corresponding detection terminals on tops of the internal heating vessel and the external heating vessel, and the detection apparatus detects the material leakage by measuring resistance between the two detection terminals corresponding to the two adjacent ends of the two adjacent bottom static wires. The present invention also provides the manufacture method. The present invention provides a design of a special heating vessel, which is easy to detect whether the material leakage occurs or not and guarantees that the related experiment and production can continue under circumstance that heating vessel is broken.

### FIELD OF THE INVENTION

The present invention relates to a heating vessel, and more particularly to a heating vessel of detecting and preventing leakage of high temperature metal material and a manufacture method thereof.

### BACKGROUND OF THE INVENTION

OLED (Organic Light Emitting Diode) possesses advantages of being all-solid state, ultra thin, no view angle limited, fast responding, room temperature workable, easy achievable flexible displaying and 3D displaying. It is supposed to be the main stream technology of next generation display. At present, heating vapor coating is a main manufacture way of the OLED elements. The coating material is heated in vacuum by using a heating vessel. The vapor coating material which is sublimable or fusable is vaporized under the high temperature circumstance and deposited on a substrate having TFT compositions or anode compositions.

During the present vapor deposition according to prior arts, a single layer vessel is commonly utilized as the vaporization vessel to be heated for vaporization. Nevertheless, micro cracks appear so common at the joint of the lateral side and the bottom of the heating vessel caused by condensation and shrinkage of the high temperature metal liquid and then material abnormal loss happens. Moreover, the high temperature liquid may outflow from the micro cracks and into the heating apparatus to lead to the internal short circuit and damage to the whole heating apparatus. Consequently, the OLED production progress is interrupted and the production quality descends. The fracture and leakage of the heating vessel are very difficult to be confirmed and hard to predict because the micro cracks are not easy to be found under the cooling status. Please refer to FIG. 1, which is a structure diagram of an OLED heating vessel according to prior art. The OLED heating vessel is utilized in the OLED vapor deposition process in prior arts. The top cap 2 comprises a vapor hole 1. The material 3 contained in the heating vessel is heated up and vaporized. Then, it can escape from the vapor hole 1 as indicated by the arrows. When the heating vessel is damaged, the material 3 may leak from the leakage points 4 and flow into the heating apparatus. The material 3 can be massively lost and the vaporized rate may drop to interrupt the production progress. Meanwhile, the material 3 is possible to be filled in and gets into the heating apparatus. There will be possibility to result the damages to the heating apparatus. Besides, the leakage points 4 of the heating vessel 2 are very difficult to be confirmed because the micro cracks are not easy to be found under the cooling status. The present heating vessel does not comprise leakage detection apparatus. It is required the visual inspection by the operator according to his experience and apparently the accuracy is low. It leads to that the maintenance to the heating vessel in time and prevention of the waste due to the material leakage cannot be achieved. The manufacture cost is inevitably increasing.

### SUMMARY OF THE INVENTION

Therefore, an objective of the present invention is to provide a heating vessel of detecting and preventing leakage of high temperature metal material to overcome the issue of the material loss due to the heating vessel damage for protecting the heating apparatus and to promote the pre-detecting ability of leakage risk.

Another objective of the present invention is to provide a manufacture method of the heating vessel of detecting and preventing leakage of high temperature metal material to make the heating vessel to overcome the issue of the material loss due to the heating vessel damage for protecting the heating apparatus and to promote the pre-detecting ability of leakage risk.

For realizing the aforesaid objective, the present invention provides a heating vessel of detecting and preventing leakage of high temperature metal material, comprising: an internal heating vessel employed for containing metal material, an external heating vessel employed to contain the internal heating vessel and to be heated by a heating apparatus and a detection apparatus; multiple bottom static wires are located between the internal heating vessel and the external heating vessel, where is close to the joint of a lateral side and a bottom of the internal heating vessel, and two ends of each of the bottom static wires are respectively connected to corresponding detection terminals on tops of the internal heating vessel and the external heating vessel, and the detection apparatus detects the material leakage by measuring resistance between the two detection terminals corresponding to the two adjacent ends of the two adjacent bottom static wires.

Material of the internal heating vessel and material of the external heating vessel are the same.

The heating vessel is employed as a heating vessel in an OLED vapor deposition process.

The internal heating vessel and the external heating vessel joint with each other at the tops as one body.

The bottom static wires are supported and fixed by insulation pads located between the internal heating vessel and the external heating vessel.

An inner diameter of the external heating vessel is larger than an outer diameter of the internal heating vessel, and a height of the external heating vessel is the same as a height of the internal heating vessel.

The detection apparatus is a multimeter.

The detection apparatus is an ohm meter.

The present invention also provides a heating vessel of detecting and preventing leakage of high temperature metal material, comprising: an internal heating vessel employed for containing metal material, an external heating vessel employed to be heated by a heating apparatus and a top cap having a vapor hole employed for escape of the vaporized metal material; the internal heating vessel is completely contained in the external heating vessel and positionally fixed relative to the external heating vessel, and an interspace exists between a side wall of the internal heating vessel and a side wall of the external heating vessel, and the top cap is fixed on tops of the internal heating vessel and the external heating vessel to cover opens of the internal heating vessel and the external heating vessel;

wherein material of the internal heating vessel and material of the external heating vessel are the same;

wherein the heating vessel is employed as a heating vessel in an OLED vapor deposition process;

wherein the internal heating vessel and the external heating vessel joint with each other at the tops as one body.

The bottom static wires are supported and fixed by insulation pads located between the internal heating vessel and the external heating vessel.

An inner diameter of the external heating vessel is larger than an outer diameter of the internal heating vessel, and a height of the external heating vessel is the same as a height of the internal heating vessel.

The detection apparatus is a multimeter.

The detection apparatus is an ohm meter.

The present invention also provides a manufacture method of the heating vessel, comprising:

Step 1, measuring an outer dimension and a height of an internal heating vessel;

Step 2, providing an external heating vessel made by the same material of the internal heating vessel, and the an inner diameter of the external heating vessel is larger than an outer diameter of the internal heating vessel, and a height of the external heating vessel is the same as a height of the internal heating vessel;

Step 3, locating multiple bottom static wires between the internal heating vessel and the external heating vessel, where is close to the joint of a lateral side and a bottom of the internal heating vessel;

Step 4, respectively connecting two ends of each of the bottom static wires to corresponding detection terminals on tops of the internal heating vessel and the external heating vessel;

Step 5, welding the tops of the internal heating vessel and the external heating vessel as one body;

Step 6, detecting the material leakage by measuring resistance between the two detection terminals corresponding to the two adjacent ends of the two adjacent bottom static wires with the detection apparatus.

The heating vessel is employed as a heating vessel in an OLED vapor deposition process.

In conclusion, the heating vessel of detecting and preventing leakage of high temperature metal material of the present invention provides a design of a special heating vessel, which is easy to detect whether the material leakage occurs or not and guarantees that the related experiment and production can continue under circumstance that heating vessel is broken. The issues of the material abnormal loss and production progress interruption due to the appeared unexpected fractures in daily usages can be overcome; the continuous steady running period of the heating apparatus is effectively promoted and the quality of the production is guaranteed.

### BRIEF DESCRIPTION OF THE DRAWINGS

The technical solution, as well as beneficial advantages, of the present invention will be apparent from the following detailed description of an embodiment of the present invention, with reference to the attached drawings.

In the attached drawings,

FIG. 1 is a structure diagram of an OLED heating vessel according to prior art;

FIG. 2 is a structure diagram of a heating vessel of detecting and preventing leakage of high temperature metal material according to the preferable embodiment of the present invention;

FIG. 3A is a diagram of a bottom circuit according to the preferable embodiment of the present invention;

FIG. 3B is a diagram of a top circuit according to the preferable embodiment of the present invention;

FIG. 4A and FIG. 4B are diagrams of leakage detecting status according to the preferable embodiment of the present invention.

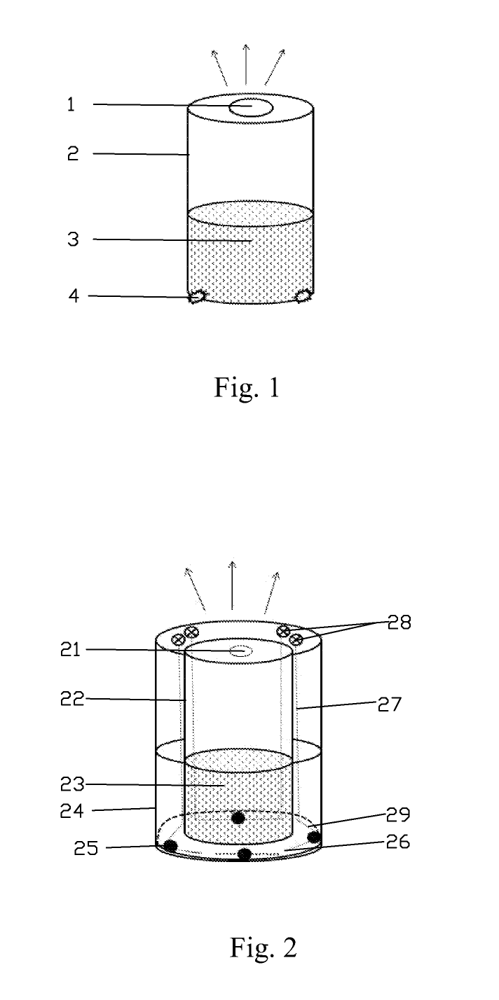

### DETAILED DESCRIPTION OF PREFERRED EMBODIMENTS

Please refer to FIG. 2, which shows a structure diagram of a heating vessel of detecting and preventing leakage of high temperature metal material according to the preferable embodiment of the present invention. The heating vessel of detecting and preventing leakage of high temperature metal material mainly comprises: an internal heating vessel 22 employed for containing metal material 23, an external heating vessel 24 employed to contain the internal heating vessel 22 and to be heated by a heating apparatus and a detection apparatus (not shown). In this preferable embodiment, the heating vessel is employed as a heating vessel in an OLED vapor deposition process. Therefore, the internal heating vessel 22 comprises a vapor hole 21. The metal material 23 is contained in the internal heating vessel 22 and can escape from the vapor hole 1 as indicated by the arrows after being heated up and vaporized; multiple bottom static wires 29 are located between the internal heating vessel 22 and the external heating vessel 24, where is close to the joint of a lateral side and a bottom of the internal heating vessel 22. In this preferable embodiment, all the bottom static wires 29 are supported and fixed by insulation pads 25 located between the internal heating vessel 22 and the external heating vessel 24. Two ends 26 of each of the bottom static wires 29 are respectively connected to corresponding detection terminals 28 on tops of the internal heating vessel 22 and the external heating vessel 24 with corresponding static wires 27, and the detection apparatus detects the material leakage by measuring resistance between the two detection terminals 28 corresponding to the two adjacent ends 26 of the two adjacent bottom static wires 29.

Material of the internal heating vessel 22 and material of the external heating vessel 24 are the same. For instance, they can be crucibles of the same material but merely with different dimensions. Therefore, the external heating vessel 24 is capable of containing the internal heating vessel 22. An inner diameter of the external heating vessel 24 can be larger than or equivalent to an outer diameter of the internal heating vessel. A height of the external heating vessel 24 can be the same as a height of the internal heating vessel 22. The internal heating vessel 22 and the external heating vessel 24 joint with each other at the tops as one body. For example, the internal heating vessel 22 and the external heating vessel 24 can sleeve joint together and be welded at the tops. Only the internal heating vessel 22 contains the metal material 23. The heated part is the outermost external heating vessel 24. The internal heating vessel 22 receives the heat by conduction or radiation for heating up the metal material 23.

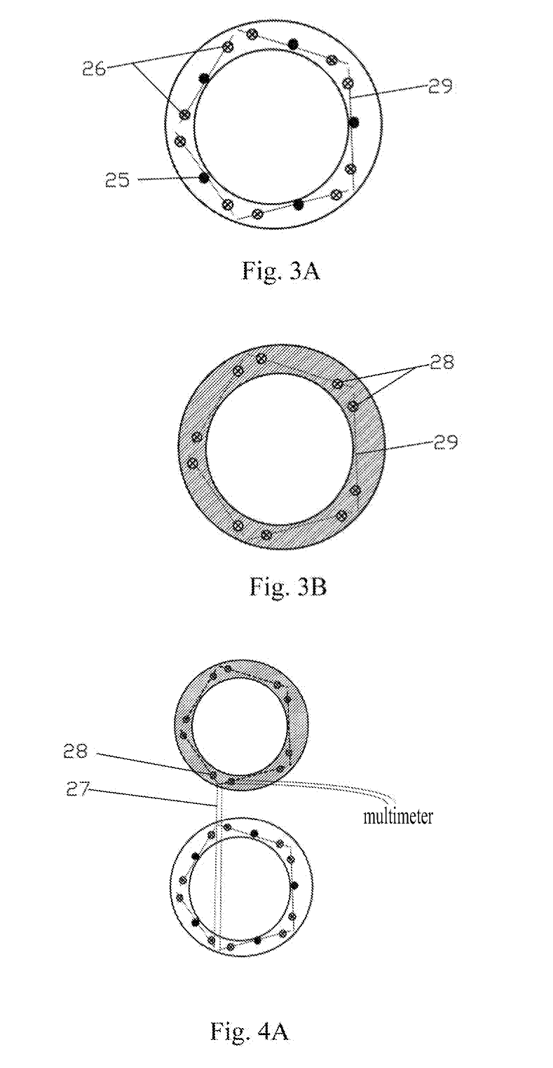

Please refer to FIG. 3A in conjunction with FIG. 3B. FIG. 3A is a diagram of a bottom circuit according to the preferable embodiment of the present invention and FIG. 3B is a diagram of a top circuit according to the preferable embodiment of the present invention. Between the internal heating vessel 22 and the external heating vessel 24, where is close to the joint of a lateral side and a bottom of the internal heating vessel 22, such as at the bottom of the external heating vessel 24, bottom static wires 29 can be arranged as in a circle. Ends 26 of any bottom static wires 29 has static wires 27 extend to the tops of the internal heating vessel 22 and the external heating vessel 24. The amount, arranged positions and arranged density can be decided based on the factors that the actual dimensions of the internal heating vessel 22 and the external heating vessel 24 and positions where the leakage easily happens. After the internal heating vessel 22 and the external heating vessel 24 are welded, all the bottom static wires 29 are supported at the center by the insulation pads 25. The ends 26 of any two bottom static wires 29 are not connected, any adjacent detection terminals 28 are not connected, either. The detection terminals 28 at the tops and the ends 26 at the bottom are connected with the static wires 27. The static wires 27 can have outer insulated heat-resistant material. As shown in FIG. 3B, the detection terminals 28 in accordance with the one bottom static wire 29 are connected via the corresponding bottom static wire 29.

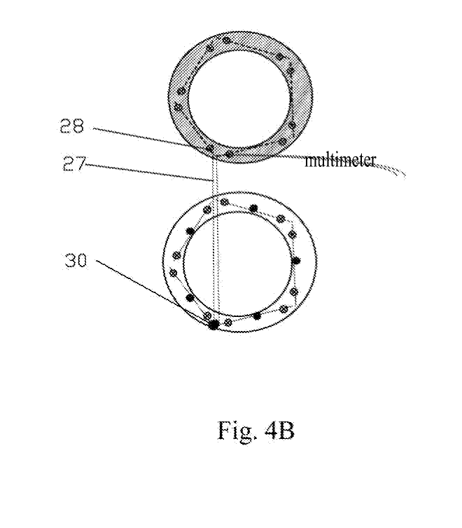

Please refer to FIG. 4A and FIG. 4B, which are diagrams of leakage detecting status according to the preferable embodiment of the present invention. As shown in FIG. 4A, in a normal circumstance, the detection apparatus is employed to measure two adjacent detection terminals 28 on the top. If the resistance is infinite, it indicates that the two adjacent bottom static wires 29 at the bottom are in open circuit state. As shown in FIG. 4B, as the leakage happens to the internal heating vessel 22, the bottom static wires 29 are jointed by the leaked high temperature metal 30. The detection apparatus measures the two adjacent detection terminals 28 on the top. The resistance is zero and a close circuit state is indicated. Accordingly, it is judged that leakage has already happened to the internal heating apparatus. By using such method and composition whether the internal heating vessel 22 is damaged and leaked or not can be judged. The detection apparatus can be a multimeter, an ohm meter or other similar detection circuit. Alternatively, the detection circuit can be controlled by programs with chips. Then, an auto scan detection can be performed to the detection terminals 28 to monitor the leaking condition in real time.

The preferable embodiment is employed as a heating vessel in an OLED vapor deposition process. With the improvement of the traditional heating vessel, the entire heating vessel can still maintain the normal production status under circumstance that internal heating vessel is broken. Meanwhile, the ability of detecting leakage is promoted. The preferable embodiment provides a new type double layer heating vessel of OLED vaporization, the material leakage and loss can be efficiently controlled and the risk of damaging the heating apparatus can be prevented. The continuous steady running period of the heating apparatus is effectively promoted and the ability of detecting the damage and the leakage of the heating vessel is advanced in the mean time.

The present invention also provides a manufacture method in accordance with the heating vessel, comprising:

Step 1, measuring an outer dimension and a height of an internal heating vessel;

Step 2, providing an external heating vessel made by the same material of the internal heating vessel, and the an inner diameter of the external heating vessel is roughly larger than or equivalent to an outer diameter of the internal heating vessel, and a height of the external heating vessel is roughly the same as a height of the internal heating vessel;

Step 3, locating multiple bottom static wires between the internal heating vessel and the external heating vessel, where is close to the joint of a lateral side and a bottom of the internal heating vessel; For instance, multiple parts of bottom static wires can be discontinuously set at the bottom around the joint of the lateral side and the bottom of the heating vessel. Any two parts are ensured not to connect with each other;

Step 4, respectively connecting two ends of each of the bottom static wires to corresponding detection terminals on tops of the internal heating vessel and the external heating vessel; With the static wires having insulated heat-resistant material, pairs of disconnected ends are lined to the top of the heating vessel and form pairs of disconnected detection terminals;

Step 5, welding the tops of the internal heating vessel and the external heating vessel as one body;

Step 6, detecting the material leakage by measuring resistance between the two detection terminals corresponding to the two adjacent ends of the two adjacent bottom static wires with the detection apparatus.

When the internal heating vessel is broken and the high temperature liquid drops on the disconnected ends at the bottom, the multimeter can be employed to detect the corresponding detection terminals to judge whether the internal heating vessel is broken and the broken location. Therefore, the ability of detecting leakage is promoted. There will be enough time to remedy for the risk of leakage. Meanwhile, the double layer design of the heating vessel can guarantee the progress of the production without interruption.

With the improvement of the traditional heating vessel according to the present invention, a present single layer vessel is improved to be a double layer heating vessel. Meanwhile, multiple static wires are discontinuously located between the internal heating vessel and the external heating vessel, where is a circle of the bottom close to the joint of the lateral side and the bottom of the internal heating vessel. Then, two adjacent disconnected ends of the static wires are lined to the top edge of the heating vessel and form two disconnected detection terminals with the static wires having insulated heat-resistant material. When the fractures and damages appear the internal heating vessel around the joint, a small amount of material leakage will connected the previously disconnected ends, which can be detected via the detection terminals. Accordingly, the pre-detecting ability of the high temperature metal material leakage is promoted. The following steady production can be guaranteed and the productivity is raised.

In conclusion, the present invention applies a design of a special heating vessel, which is easy to detect whether the material leakage occurs or not by using the detection apparatus, such as a multimeter and guarantees that the related experiment and production can continue under circumstance that heating vessel is broken. The issues of the material abnormal loss and production progress interruption due to the appeared unexpected fractures in daily usages can be overcome; the continuous steady running period of the heating apparatus is effectively promoted and the quality of the production is guaranteed.

Above are only specific embodiments of the present invention, the scope of the present invention is not limited to this, and to any persons who are skilled in the art, change or replacement which is easily derived should be covered by the protected scope of the invention. Thus, the protected scope of the invention should go by the subject claims.

What is claimed is:

1. A heating vessel of detecting and preventing leakage of high temperature metal material, comprising: an internal heating vessel employed for containing metal material, an external heating vessel employed to contain the internal heating vessel and to be heated by a heating apparatus and a detection apparatus; multiple bottom static wires are located between the internal heating vessel and the external heating vessel, where is close to the joint of a lateral side and a bottom of the internal heating vessel, and two ends of each of the bottom static wires are respectively connected to corresponding detection terminals on tops of the internal heating vessel and the external heating vessel, and the detection apparatus detects the material leakage by measuring resistance between the two detection terminals corresponding to the two adjacent ends of the two adjacent bottom static wires.

2. The heating vessel of detecting and preventing leakage of high temperature metal material according to claim 1, wherein material of the internal heating vessel and material of the external heating vessel are the same.

3. The heating vessel of detecting and preventing leakage of high temperature metal material according to claim 1, wherein the heating vessel is employed as a heating vessel in an OLED vapor deposition process.

4. The heating vessel of detecting and preventing leakage of high temperature metal material according to claim 1, wherein the internal heating vessel and the external heating vessel joint with each other at the tops as one body.

5. The heating vessel of detecting and preventing leakage of high temperature metal material according to claim 1, wherein the bottom static wires are supported and fixed by insulation pads located between the internal heating vessel and the external heating vessel.

6. The heating vessel of detecting and preventing leakage of high temperature metal material according to claim 1, wherein an inner diameter of the external heating vessel is larger than an outer diameter of the internal heating vessel, and a height of the external heating vessel is the same as a height of the internal heating vessel.

7. The heating vessel of detecting and preventing leakage of high temperature metal material according to claim 1, wherein the detection apparatus is a multimeter.

8. The heating vessel of detecting and preventing leakage of high temperature metal material according to claim 1, wherein the detection apparatus is an ohm meter.

9. A heating vessel of detecting and preventing leakage of high temperature metal material, comprising: an internal heating vessel employed for containing metal material, an external heating vessel employed to be heated by a heating apparatus and a top cap having a vapor hole employed for escape of the vaporized metal material; the internal heating vessel is completely contained in the external heating vessel and positionally fixed relative to the external heating vessel, and an interspace exists between a side wall of the internal heating vessel and a side wall of the external heating vessel, and the top cap is fixed on tops of the internal heating vessel and the external heating vessel to cover opens of the internal heating vessel and the external heating vessel;
wherein material of the internal heating vessel and material of the external heating vessel are the same;
wherein the heating vessel is employed as a heating vessel in an OLED vapor deposition process;
wherein the internal heating vessel and the external heating vessel joint with each other at the tops as one body.

10. The heating vessel of detecting and preventing leakage of high temperature metal material according to claim 9, wherein the bottom static wires are supported and fixed by insulation pads located between the internal heating vessel and the external heating vessel.

11. The heating vessel of detecting and preventing leakage of high temperature metal material according to claim 9, wherein an inner diameter of the external heating vessel is larger than an outer diameter of the internal heating vessel, and a height of the external heating vessel is the same as a height of the internal heating vessel.

12. The heating vessel of detecting and preventing leakage of high temperature metal material according to claim 9, wherein detection apparatus is a multimeter.

13. The heating vessel of detecting and preventing leakage of high temperature metal material according to claim 9, wherein the detection apparatus is an ohm meter.

14. A manufacture method of the heating vessel according to claim 1, comprising:
Step 1, measuring an outer dimension and a height of an internal heating vessel;
Step 2, providing an external heating vessel made by the same material of the internal heating vessel, and the an inner diameter of the external heating vessel is larger than an outer diameter of the internal heating vessel, and a height of the external heating vessel is the same as a height of the internal heating vessel;
Step 3, locating multiple bottom static wires between the internal heating vessel and the external heating vessel, where is close to the joint of a lateral side and a bottom of the internal heating vessel;
Step 4, respectively connecting two ends of each of the bottom static wires to corresponding detection terminals on tops of the internal heating vessel and the external heating vessel;
Step 5, welding the tops of the internal heating vessel and the external heating vessel as one body;
Step 6, detecting the material leakage by measuring resistance between the two detection terminals corresponding to the two adjacent ends of the two adjacent bottom static wires with the detection apparatus.

15. The manufacture method according to claim 14, wherein the heating vessel is employed as a heating vessel in an OLED vapor deposition process.
